(19) United States
(12) Patent Application Publication
(10) Pub. No.: US 2009/0065786 A1
(43) Pub. Date: Mar. 12, 2009

(54) PROCESS FOR PRODUCING THIN NITRIDE FILM ON SAPPHIRE SUBSTRATE AND THIN NITRIDE FILM PRODUCING APPARATUS

(75) Inventors: Masatomo Sumiya, Shizuoka (JP); Shunro Fuke, Shizuoka (JP)

Correspondence Address: OBLON, SPIVAK, MCCLELLAND MAIER & NEUSTADT, P.C., 1940 DUKE STREET, ALEXANDRIA, VA, 22314, US

(73) Assignees: JAPAN SCIENCE AND TECHNOLOGY AGENCY, Kawaguchi-shi (JP); National University Corporation Shizuoka Univ., Shizuoka-shi (JP)

(21) Appl. No.: 11/909,361

(22) PCT Filed: Mar. 14, 2006
(86) PCT No.: PCT/JP2006/304942

§ 371 Date: Sep. 21, 2007

(30) Foreign Application Priority Data
Mar. 23, 2005 (JP) 2005-084264

(51) Int. Cl. H01L 29/20; H01L 21/205

(52) U.S. Cl. 257/76; 438/479; 257/E29.089; 257/E21.113

(57) ABSTRACT

A method for growing a nitride thin film on a sapphire substrate, in which using no resists, miniaturization can be accomplished while relieving vexatious complication of the process; and a relevant device using nitride thin film. There is provided a method for growing a nitride thin film on a sapphire substrate, comprising irradiating a sapphire substrate having undergone high temperature hydrogen treatment with electron beams and depositing a nitride thin film on the substrate having undergone the electron beam irradiation by using the metal-organic chemical vapor deposition technique to thereby accomplish patterning of nitride thin film.

### TECHNICAL FIELD

The present invention relates to a method for growing nitride thin film on a sapphire substrate and a device using the nitride thin film.

### BACKGROUND ART

There have been the following patent documents 1 to 5 on a method for controlling the polar structure of the nitride thin film. In any of these documents, various efforts were made to an interfacial layer (such as a low temperature buffer layer and a metallic layer) lying between the substrate and the nitride thin film, but no attention was focused on the processing of the substrate itself. In addition, no consideration has been given to the growth method of a nitride thin film having two different polar structures simultaneously on a sapphire substrate.

Inventors of the present invention have already demonstrated that the growth of a GaN thin film, by the metal-organic chemical vapor deposition (MOCVD) method, on a high-temperature hydrogen treated sapphire substrate treated partially in a nitric acid solution in advance can invite growth of a GaN thin film having both polarity (stereo-selective growth) simultaneously depending on the treatment condition of the substrate. (See patent document 6 below).

This demonstration enables applications towards optoelectronics and electron devices, which include an electric field induced photonic crystal and a new patterning method toward device isolation technology, by making use of the electronic state difference due to the polar structure and selective etching property in alkaline solution and the like.

[Patent document l] Japanese Patent Publication No. 2002-270525.
[Patent document 2] Japanese Patent Publication No. 2004-022563.
[Patent document 3] Japanese Patent Publication No. 2001-185487.
[Patent document 4] Japanese Patent Publication No. 2003-142406.
[Patent document 5] Japanese Patent Publication No. 06-0326416.
[Patent document 6] Japanese Patent Publication No. 2005-026407 (PCT/JP2004/008351)
[Non-Patent document 1] M. Takabe et. al., Mat. Res. Soc. Symp. Proc. Vol. 798, 305 (2004).

### DISCLOSURE OF INVENTION

In the conventional methods described above, fine patterning was difficult in the stereo-selective growth because of the effects of the photoresist made on the substrate surface.

As described above, while nitride thin film was successfully obtained by partial treatment of the sapphire substrate in a nitric acid solution, patterning of a micron meter order was difficult because of difficulty in selecting a resist material tolerant to alkaline solution.

In addition, a method of controlling the polar structure of the grown thin film over the substrate surface by patterning the low temperature buffer layer using a mask pattern was reported by a research group of Germany.

This method, however, has such a problem that a process comprising a bunch of steps including deposition on the low temperature buffer layer; mask alignment and etching; and deposition of the nitride thin film must be repeated many times. That is, this method has problems of difficulty in fine pattern and the process complication.

In view of the situation described above, the present invention provides a method of growing a nitride thin film on a sapphire substrate without using a resist, which conducts improvement in fine patterning and suppresses process complication, and a device using the nitride thin film.

In order to achieve the above objects, the present invention provides:

[1] a method of growth of a nitride thin film on a sapphire substrate comprising steps of irradiating an electron beam on the sapphire substrate treated by high temperature hydrogen in advance, and depositing a nitride thin film by the metal-organic chemical vapor deposition method on the substrate treated by the electron beam, thereby forming a pattern of the nitride thin film.

[2] a method of growth of a nitride thin film on a sapphire substrate comprising steps of: irradiating an electron beam with a fine width on the sapphire substrate treated by high temperature hydrogen in advance; depositing a nitride thin film by metal-organic chemical vapor deposition method on the substrate treated by the electron beam; and etching the nitride thin film in an alkaline solution, thereby forming a fine pattern of the nitride thin film corresponding to the fine width of the irradiating electron beam.

[3] the method of growth of a nitride thin film on a sapphire substrate in the above description [1] or [2], wherein the nitride thin film is a GaN thin film.

[4] the method of growth of a nitride thin film on a sapphire substrate in the above description [1], [2], or [3], wherein the electron beam is an electron beam generated from the Reflection High Energy Electron Diffraction (RHEED).

[5] the method of growth of a nitride thin film on a sapphire substrate in the above description [1], [2], or [3], wherein the irradiation by the electron beam from the Reflection High Energy Electron Diffraction (RHEED) is performed at room temperature.

[6] the method of growth of a nitride thin film on a sapphire substrate in the above description [5], wherein the irradiation is performed for one or more minutes.

[7] the method of growth of a nitride thin film on a sapphire substrate in the above description [1], [2], or [3], wherein the electron beam is an electron beam of the electron beam lithography.

[8] the method of growth of a nitride thin film on a sapphire substrate in the above description [1] [2], or [3], wherein the high temperature hydrogen treatment is a hydrogen treatment at or above 1000° C. for about 20 minutes.

[9] the method of growth of a nitride thin film on a sapphire substrate in the above description [1], [2], or [3], wherein the nitride thin film is grown while a nitride thin film having a different polar face is simultaneously grown.

[10] the method of growth of a nitride thin film on a sapphire substrate in the above description [1], [2], or [3], wherein an electrode is formed on the substrate to apply an electric field to the nitride thin film whose polar structure and its position are controlled.

[11] the method of growth of a nitride thin film on a sapphire substrate in the above description [1], [2], or [3], wherein the fine pattern of the nitride thin film is stripes having intervals of several tens of μm between each stripe.

[12] a device using a nitride thin film, wherein the nitride thin film device is realized by using the method of growth of a nitride thin film on a sapphire substrate in any one of the above descriptions [1] to [11].

### BRIEF DESCRIPTION OF THE DRAWINGS

FIG. 1 shows a stereo-selective growth of a GaN thin film on a sapphire substrate treated by irradiation of an electron beam generated from RHEED according to the present invention.

FIG. 2 shows a sapphire substrate (0001) surface after high temperature hydrogen cleaning treatment.

FIG. 3 shows water droplets one of which is on a substrate treated by the high temperature hydrogen only, and the other of which is on a substrate to which a treatment by an electron beam of RHEED was performed additionally.

FIG. 4 is an explanatory illustration of a GaN thin film treatment by an electron beam of RHEED according to the present invention.

FIG. 5 shows a side view of the observation measurement of the sapphire surfaces one of which was obtained by the high temperature hydrogen treatment only, and the other one of which was obtained by the additional treatment by the electron beam irradiation.

FIG. 6 shows a top view of the observation measurement of the sapphire surfaces one of which was obtained by the high temperature hydrogen treatment only and the other of which was obtained by the additional treatment by the electron beam irradiation.

FIG. 7 shows another embodiment according to the present invention showing a GaN thin film growth on a sapphire substrate treated by the electron beam lithography.

FIG. 8 shows another embodiment according to the present invention showing a GaN thin film growth step on a sapphire substrate treated by the electron beam lithography.

FIG. 9 shows another embodiment according to the present invention showing an optical microscope image of a GaN thin film grown on a sapphire substrate treated by the electron beam lithography.

### BEST MODE FOR CARRYING OUT THE INVENTION

The method for growth of a nitride thin film on a sapphire substrate and the device using the nitride thin film according to the present invention are based on the following processes and the effect obtained thereby. Firstly, a sapphire substrate treated by high temperature hydrogen in advance was irradiated with an electron beam from the RHEED apparatus for one minute or more at room temperature while the RHEED pattern of the sapphire substrate was observed. Secondary, a GaN thin film of 1 μm thick was deposited by the metal-organic chemical vapor deposition method on the substrate treated by the electron beam. Then an etching in a KOH solution selectively removed a part of a line about 200 μm wide which corresponds to a part of the substrate treated by the electron beam.

Thus, the treatment by electron beam of the sapphire substrate in this way enables fine processing of the sapphire substrate without using a resist. Furthermore, when a GaN thin film was grown on the substrate after electron beam irradiation from the RHEED apparatus, selectivity of the polar face appeared.

### EMBODIMENTS

Embodiments according to the present invention will be described in detail in the following.

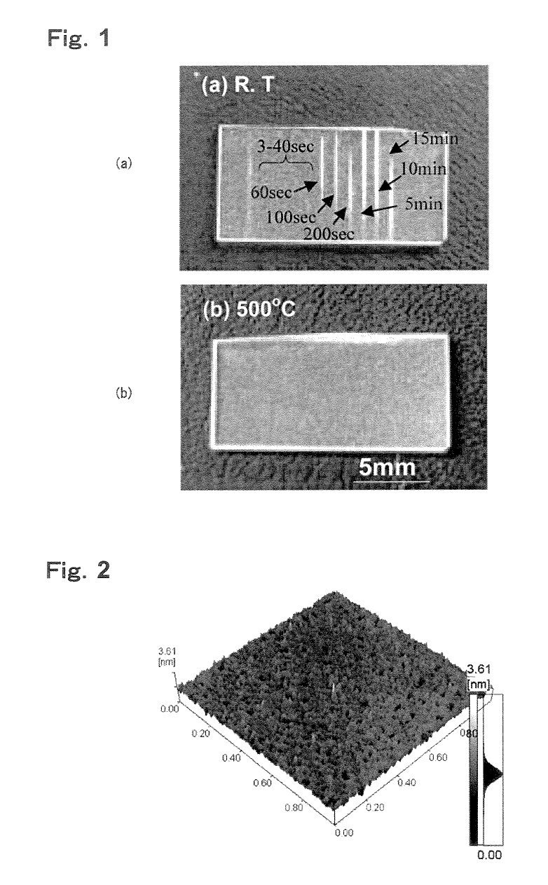

FIG. 1 shows a first embodiment according to the present invention, showing a stereo-selective growth of a GaN thin film on a sapphire substrate treated by irradiation of an electron beam of RHEED.

First, a sapphire substrate treated by hydrogen at high temperature for 20 minutes in advance was irradiated by an electron beam from the RHEED apparatus with an acceleration voltage of 20 kV under various conditions from at room temperature to 500° C. for 3 seconds to 2 hours (RHEED observation). Then, without the second high temperature hydrogen treatment, a GaN thin film was grown by using the two-step metal-organic chemical vapor deposition method on the sapphire substrate a part of which was treated by electron beam.

FIG. 1(a) and 1(b) show surface photograph of the GaN thin film on the sapphire substrate treated by electron beam for various duration of time at room temperature and at 500° C., respectively.

As shown in FIG. 1(a), although the polar structure is not clear, a thin film considered GaN grew on the part of the substrate surface by electron beam treatment at room temperature for 60 seconds or more (regions with several hundreds of μm in width which look white). On the other part of the substrate surface, a planar GaN thin film with Ga face (+c) polarity grew. On the other hand, at the raised temperature treated by the electron beam, despite various treatment duration up to 2 hours, +c GaN thin film grew (See FIG. 1(b)).

Then, the sample shown in FIG. 1(a) was immersed in a 10 wt % KOH solution for 2 hours. In the result, only white line regions were clearly etched off. From these results, it is clear that fine pattern of the +c GaN thin film was realized by the electron beam treatment of the sapphire substrate at room temperature.

In addition, treatment of a sapphire substrate generally requires a hydrogen treatment at or above a temperature of 1000° C. For example, a hydrogen treatment at 1000° C. was performed here. Next, a part of the substrate surface was treated by electron beam from the RHEED apparatus of 45 μA in beam current and 0.2 mmφ in diameter with the irradiation for 2.5 minutes per one step, and subsequently, the substrate was moved by 100 μm. This operation was repeated till the substrate moved by 4.5 mm.

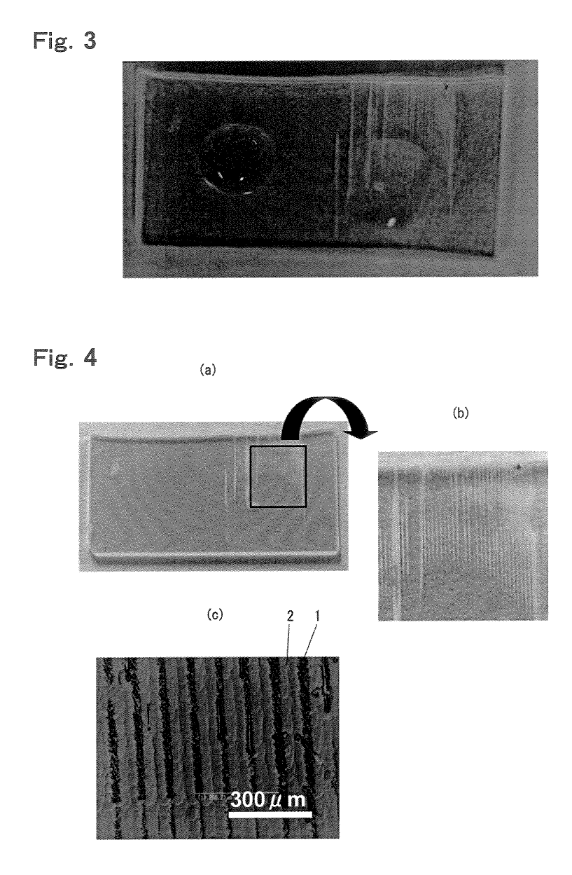

FIG. 2 shows a sapphire substrate (0001) surface after high temperature hydrogen cleaning treatment. FIG. 3 shows water droplets one of which is on a substrate treated by the high temperature hydrogen only, and the other of which is on a substrate to which a treatment by an electron beam of RHEED was performed additionally.

FIG. 4 is an explanatory illustration of a GaN thin film growth after the treatment by electron beam of RHEED according to the present invention. FIG. 4(a) is a sapphire substrate on which a GaN thin film was grown, FIG. 4(b) is an enlarged view of a part of the GaN thin film, and FIG. 4(c) is a further enlarged view of the GaN thin film having a stripe shape. As shown in FIG. 4(c), both of the stripe shaped GaN thin film 1 and the flat GaN thin film with Ga face (+c) polarity 2 are formed.

In the following, a second embodiment of the present invention is described, which includes a treatment method of a sapphire substrate by the electron beam lithography.

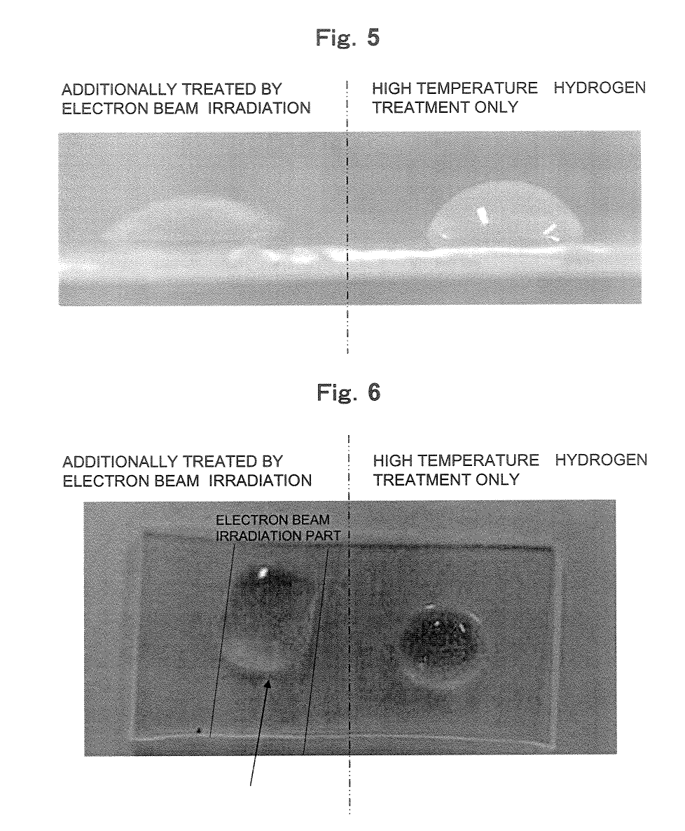

FIGS. 5 and 6 show a side view and a top view, respectively, of the observation measurement of a sapphire surface one of which was obtained by the high temperature hydrogen treatment only, and the other of which was obtained by the additional treatment by the electron beam irradiation. When attention is paid on a contact angle of a water droplet of 10 μl on the surface of the sapphire, the contact angle is clearly different between the case with high temperature hydrogen treatment only and the case with additional electron beam irradiation.

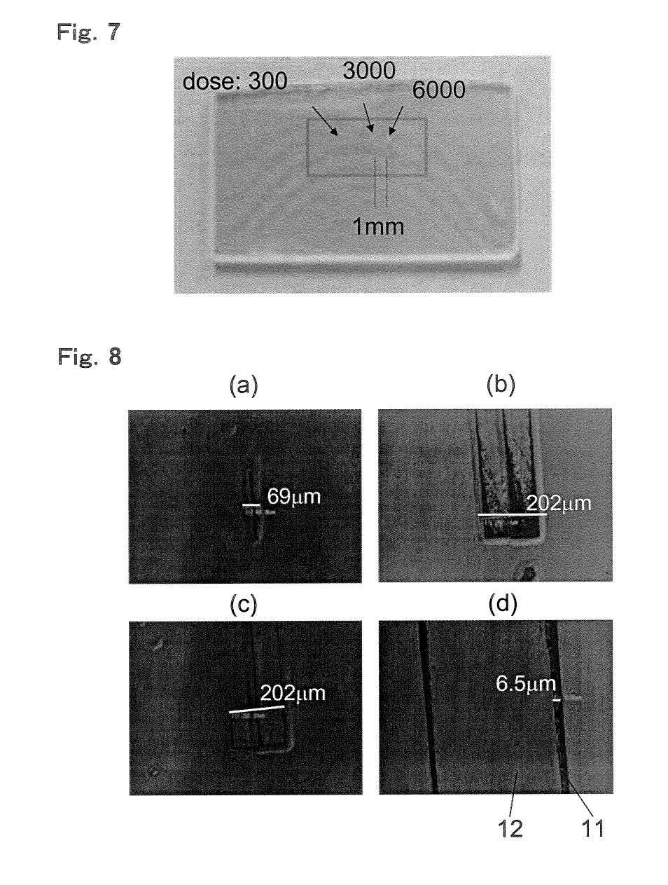

FIG. 7 shows another embodiment according to the present invention showing a GaN thin film growth after the treatment by the electron beam lithography. In the electron beam lithography, a beam current was 2nA and the dose was 6000, 3000, 1000, 300, and 100 μC/cm².

FIG. 8 shows another embodiment according to the present invention showing a GaN thin film growth steps by the electron beam lithography treatment.

What are shown in FIG. 8(a) to (c) are formed when the GaN thin film was grown by the two-step metal-organic chemical vapor deposition method on the sapphire substrate treated by the electron beam lithography. After immersion for 2 hours in KOH solution, a fine pattern 11 of line width of 6.50 μm and a planar GaN thin film 12 with Ga face (+c) polarity are formed.

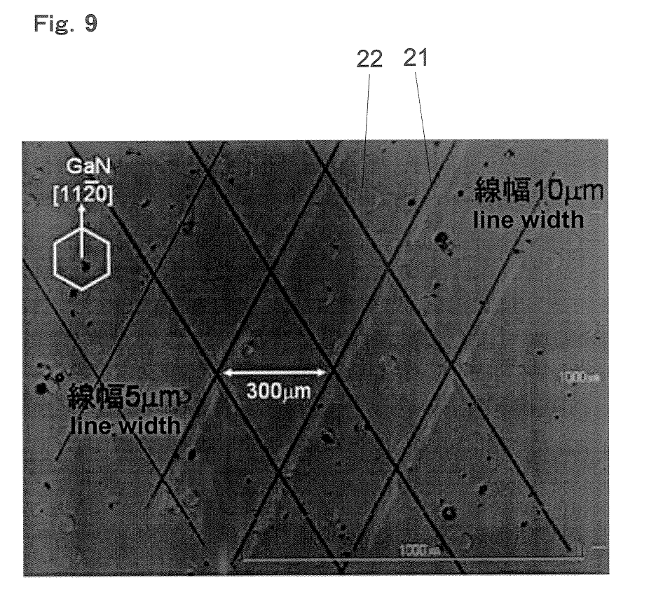

FIG. 9 shows another embodiment according to the present invention showing an optical microscope image of a GaN thin film grown on a sapphire substrate treated by the electron beam lithography. A fine pattern 21 of line width of 5 μm to 10 μm and a planar GaN thin film 22 with Ga face (+c) polarity are clearly formed.

Other than the electron beam described above, electron beams such as that used in the scanning electron microscope (SEM) and transmission electron microscope (TEM) can be used.

As described above, according to the present invention, the nitride thin film on a sapphire substrate can be grown with fine pattern, without using a resist, and with improvement in reducing the process complication.

Also, controllability of the polar structure of the nitride thin film by the electron beam treatment at room temperature was presented for the first time by the present invention. Especially, by using the electron beam from the RHEED, there are such advantages that accurate information on the orientation within the surface of the sapphire substrate can be obtained, and that the orientation of the nitride thin film grown on the sapphire substrate can be determined. Further, by focusing the electron beam from the electron beam lithography apparatus, further refinement of the pattern and improvement in property of the nitride thin film can be realized.

The present invention is not limited to the above-described embodiments. Numerous modifications and variations of the present invention are possible in light of the spirit of the present invention, and they are not excluded from the scope of the present invention.

### INDUSTRIAL APPLICABILITY

The method of growth of nitride thin film on a sapphire substrate and the device using the nitride thin film disclosed in the present invention can be widely applied to short wavelength light emitting devices made from the nitride semiconductor and manufacturing industry of bulk material.

1. A method of growth of a nitride thin film on a sapphire substrate comprising steps of irradiating an electron beam on the sapphire substrate treated by high temperature hydrogen in advance, and depositing a nitride thin film by the metal-organic chemical vapor deposition method on the substrate treated by the electron beam, thereby forming a pattern of the nitride thin film.

2. A method of growth of a nitride thin film on a sapphire substrate comprising steps of:
(a) irradiating an electron beam with a fine width on the sapphire substrate treated by high temperature hydrogen in advance;
(b) depositing a nitride thin film by the metal-organic chemical vapor deposition method on the substrate treated by the electron beam; and
(c) etching the nitride thin film in an alkaline solution, thereby forming a fine pattern of the nitride thin film corresponding to the fine width of the irradiating electron beam.

3. The method of growth of a nitride thin film on a sapphire substrate according to claim 1 or 2, wherein the nitride thin film is a GaN thin film.

4. The method of growth of a nitride thin film on a sapphire substrate according to claim 1, 2, or 3, wherein the electron beam is an electron beam generated from the Reflection High Energy Electron Diffraction (RHEED).

5. The method of growth of a nitride thin film on a sapphire substrate according to claim 1, 2, or 3, wherein the irradiation by electron beam from the Reflection High Energy Electron Diffraction (RHEED) is performed at room temperature.

6. The method of growth of a nitride thin film on a sapphire substrate according to claim 5, wherein the irradiation is performed for one or more minutes.

7. The method of growth of a nitride thin film on a sapphire substrate according to 1, 2, or 3, wherein the electron beam is an electron beam of the electron beam lithography.

8. The method of growth of a nitride thin film on a sapphire substrate according to claim 1, 2, or 3, wherein the high temperature hydrogen treatment is a hydrogen treatment at or above 1000° C. for about 20 minutes.

9. The method of growth of a nitride thin film on a sapphire substrate according to claim 1, 2, or 3, wherein the nitride thin film is grown while a nitride thin film having a different polar face is simultaneously grown.

10. The method of growth of a nitride thin film on a sapphire substrate according to claim 1, 2, or 3, wherein an electrode is formed on the substrate to apply an electric field to the nitride thin film whose polar structure and its position are controlled.

11. The method of growth of a nitride thin film on a sapphire substrate according to claim 1, 2, or 3, wherein the fine pattern of the nitride thin film is stripes having intervals of several tens of μm between each stripe.

12. A device using a nitride thin film, wherein the device is realized by using the method of growth of the nitride thin film on a sapphire substrate in any one of the above claims 1 to 11.
